(19) United States
(12) Patent Application Publication
(10) Pub. No.: US 2024/0284677 A1
(43) Pub. Date: Aug. 22, 2024

(54) SEMICONDUCTOR DEVICE AND METHOD FOR MANUFACTURING THE SAME

(71) Applicant: Kioxia Corporation, Tokyo (JP)

(72) Inventors: Chihiro UMEDA, Yokkaichi Mie (JP); Yuta KAMIYA, Nagoya Aichi (JP); Tomohisa IINO, Yokkaichi Mie (JP); Masaki NOGUCHI, Yokkaichi Mie (JP); Akira TAKASHIMA, Fuchu Tokyo (JP); Yusuke NAKAJIMA, Yokkaichi Mie (JP)

(21) Appl. No.: 18/443,531

(22) Filed: Feb. 16, 2024

(30) Foreign Application Priority Data
Feb. 17, 2023 (JP) 2023-023250

(51) Int. Cl. H10B 43/30; H10B 43/27

(52) U.S. Cl. CPC H10B 43/30; H10B 43/27

(57) ABSTRACT

A semiconductor device includes electrode layers and first insulating films alternately stacked on top of one another; a second insulating film extending along an upper surface, a lower surface, and a side surface of one of electrode layers; a charge storage layer extending along a side surface of the second insulating film with a third insulating film interposed therebetween; and a semiconductor layer extending along a side surface of the charge storage layer with a fourth insulating film interposed therebetween. A hydrogen concentration in the fourth insulating film is equal to or higher than a hydrogen concentration in the charge storage layer, which is equal to or higher than a hydrogen concentration in the third insulating film, which is equal to or higher than a hydrogen concentration in the second insulating film.

### CROSS-REFERENCE TO RELATED APPLICATION

This application is based upon and claims the benefit of priority from Japanese Patent Application No. 2023-023250, filed Feb. 17, 2023, the entire contents of which are incorporated herein by reference.

### FIELD

Embodiments described herein relate generally to a semiconductor device and a method for manufacturing the same.

### BACKGROUND

When manufacturing a three-dimensional semiconductor memory, there is a problem how to select a structure and a forming method of a memory cell.

### DESCRIPTION OF THE DRAWINGS

FIG. 1 is a perspective view showing a structure of a semiconductor device according to the first embodiment.

FIG. 2 is a cross-sectional view (1/4) showing a method for manufacturing a semiconductor device according to the first embodiment.

FIG. 3 is a cross-sectional view (2/4) showing the method for manufacturing a semiconductor device according to the first embodiment.

FIG. 4 is a cross-sectional view (3/4) showing the method for manufacturing a semiconductor device according to the first embodiment.

FIG. 5 is a cross-sectional view (4/4) showing the method for manufacturing a semiconductor device according to the first embodiment.

FIGS. 6A and 6B are cross-sectional views showing details of the method for manufacturing a semiconductor device according to the first embodiment.

FIGS. 7A and 7B are cross-sectional views for comparing the method for manufacturing a semiconductor device according to a comparative example of the first embodiment and the method for manufacturing a semiconductor device according to the first embodiment.

FIGS. 8A and 8B are graphs showing characteristics of the semiconductor device of the first embodiment.

FIGS. 9A and 9B are cross-sectional views showing details of the method for manufacturing a semiconductor device according to the first embodiment.

FIGS. 10A and 10B are cross-sectional views showing details of the method for manufacturing a semiconductor device according to a modification example of the first embodiment.

### DETAILED DESCRIPTION

Embodiments provide a semiconductor device capable of forming a suitable memory cell and a method for manufacturing the same.

In general, according to one embodiment, a semiconductor device includes a stacked film including a plurality of electrode layers and a plurality of first insulating films alternately stacked on top of one another; a second insulating film extending along an upper surface, a lower surface, and a side surface of at least one of the plurality of electrode layers; a charge storage layer extending along a side surface of the second insulating film with a third insulating film interposed between the second insulating film and the charge storage layer; and a semiconductor layer extending along a side surface of the charge storage layer with a fourth insulating film interposed between the charge storage layer and the semiconductor layer. A hydrogen concentration in the fourth insulating film is equal to or higher than a hydrogen concentration in the charge storage layer. The hydrogen concentration in the charge storage layer is equal to or higher than a hydrogen concentration in the third insulating film. The hydrogen concentration in the third insulating film is equal to or higher than a hydrogen concentration in the second insulating film.

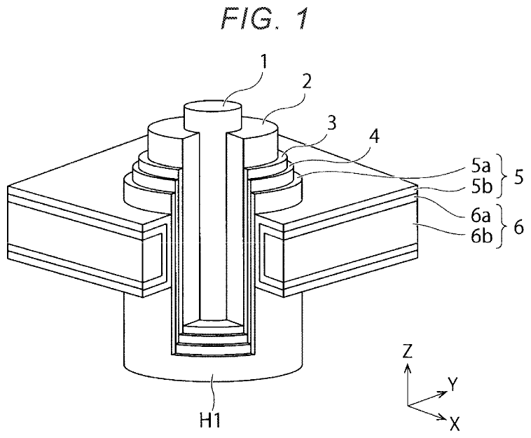

Hereinafter, embodiments of the present disclosure will be described with reference to the drawings. In FIGS. 1 to 10B, the same components are denoted by the same reference symbols, and redundant description will be omitted.

### First Embodiment

FIG. 1 is a perspective view showing a structure of a semiconductor device according to the first embodiment. The semiconductor device of the present embodiment includes, for example, a three-dimensional semiconductor memory.

The semiconductor device of the present embodiment includes a core insulating film 1, a channel semiconductor layer 2, a tunnel insulating film 3, a charge storage layer 4, a block insulating film 5, and an electrode layer 6. The block insulating film 5 includes an insulating film 5a and an insulating film 5b. The electrode layer 6 includes a barrier metal layer 6a and an electrode material layer 6b. The tunnel insulating film 3 is an example of a fourth insulating film. The insulating film 5a is an example of a third insulating film. The insulating film 5b is an example of a second insulating film.

In FIG. 1, a plurality of electrode layers and a plurality of insulating films are alternately stacked on a substrate, and a memory hole H1 is provided in the electrode layers and the insulating films. FIG. 1 shows one of the electrode layers, the electrode layer 6. The electrode layers function as, for example, a word line of the three-dimensional semiconductor memory. FIG. 1 shows X and Y directions parallel to a surface of the substrate and perpendicular to each other, and a Z direction perpendicular to the surface of the substrate. In the present specification, a +Z direction is treated as an upward direction, and a −Z direction is treated as a downward direction. The −Z direction may or may not coincide with a gravity direction.

The core insulating film 1, the channel semiconductor layer 2, the tunnel insulating film 3, the charge storage layer 4, and the insulating film 5a are formed in the memory hole H1 and form a memory cell of the three-dimensional semiconductor memory. The insulating film 5a is formed on side surfaces of the electrode layer and the insulating film in the memory hole H1, and the charge storage layer 4 is formed on a side surface of the insulating film 5a. The charge storage layer 4 may accumulate a signal charge of the three-dimensional semiconductor memory. The tunnel insulating film 3 is formed on a side surface of the charge storage layer 4, and the channel semiconductor layer 2 is formed on a side surface of the tunnel insulating film 3. The channel semiconductor layer 2 functions as a channel of the three-dimensional semiconductor memory. The core insulating film 1 is formed on a side surface of the channel semiconductor layer 2.

The insulating film 5a is, for example, a silicon oxide (SiO₂) film. The charge storage layer 4 is, for example, a silicon nitride (SiN) film. The tunnel insulating film 3 is, for example, a silicon oxynitride (SiON) film. The tunnel insulating film 3 may be the SiO₂ film. The channel semiconductor layer 2 is, for example, a polysilicon layer. The core insulating film 1 is, for example, a SiO₂ film.

The insulating film 5b, the barrier metal layer 6a, and the electrode material layer 6b are formed between two insulating films among the plurality of insulating films, and are sequentially formed on a lower surface of an upper insulating film, an upper surface of a lower insulating film, and the side surface of the insulating film 5a. Therefore, the insulating film 5b is formed on an upper surface, a lower surface, and a side surface of the electrode layer 6, and the insulating film 5a is formed on a side surface of the insulating film 5b. The plurality of insulating films are examples of the first insulating film.

The insulating film 5b is, for example, a hafnium oxide (HfOₓ) film. The insulating film 5b may be an aluminum oxide (AlOₓ) film or a zirconium oxide (ZrOₓ) film (x represents a positive real number). The barrier metal layer 6a is, for example, a titanium nitride (TiN) film. The electrode material layer 6b is, for example, a tungsten (W) layer.

The tunnel insulating film 3, the charge storage layer 4, the insulating film 5a, the insulating film 5b, and the like of the present embodiment contain hydrogen, for example, contain hydrogen atoms as impurity atoms. For example, in a case of forming the SiO₂ film, the SiN film, the SiON film, or the like described above, the hydrogen atoms penetrate into the tunnel insulating film 3, the charge storage layer 4, the insulating film 5a, the insulating film 5b, and the like by using a source gas containing silicon and hydrogen. When hydrogen concentrations in the tunnel insulating film 3, the charge storage layer 4, the insulating film 5a, and the insulating film 5b are denoted by A₃, A₄, A₅ₐ, and A_{5b}, respectively, in the present embodiment, the relationship of A₃≥A₄≥A₅ₐ≥A_{5b} is established. The hydrogen concentration A₄ in the charge storage layer 4 of the present embodiment is, for example, equal to or lower than 1.0×10²⁰ atoms/cm³. Further details of the hydrogen concentrations A₃, A₄, A₅ₐ, and A_{5b} of the present embodiment will be described below.

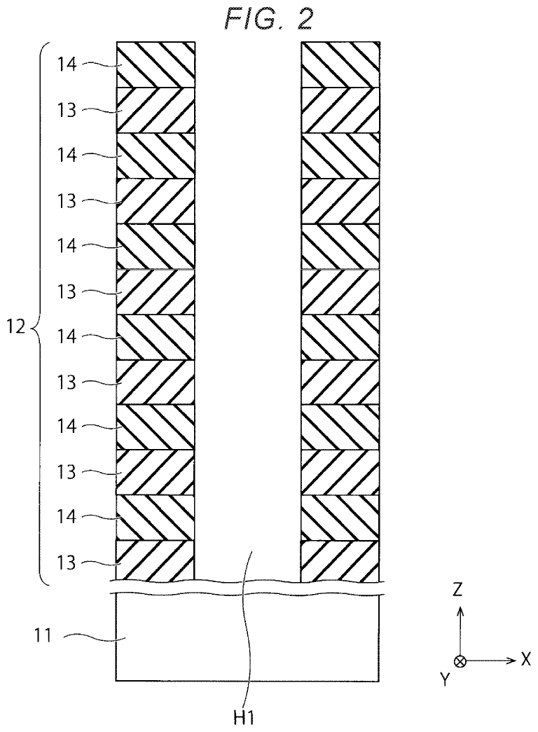

FIGS. 2 to 5 are cross-sectional views showing the method for manufacturing a semiconductor device according to the first embodiment.

First, the substrate 11 is prepared, and a stacked film 12 alternately including a plurality of sacrificial layers 13 and a plurality of insulating films 14 is formed on the substrate 11 (FIG. 2). The stacked film 12 is formed by alternately stacking the plurality of sacrificial layers 13 and the plurality of insulating films 14 on the substrate 11. The stacked film 12 may be directly formed on the substrate 11 or may be formed on the substrate 11 through other layers. The substrate 11 is, for example, a semiconductor substrate such as a silicon (Si) substrate. The sacrificial layer 13 is, for example, a SiN film. The insulating film 14 is, for example, a SiO₂ film. The sacrificial layer 13 is an example of the first layer, and the insulating film 14 is an example of the first insulating film.

Next, a plurality of memory holes H1 are formed in the stacked film 12 by photolithography and reactive ion etching (RIE) (FIG. 2). FIG. 2 shows one of the memory holes H1. Each of the memory holes H1 of the present embodiment has a circular shape in a plan view and penetrates the stacked film 12.

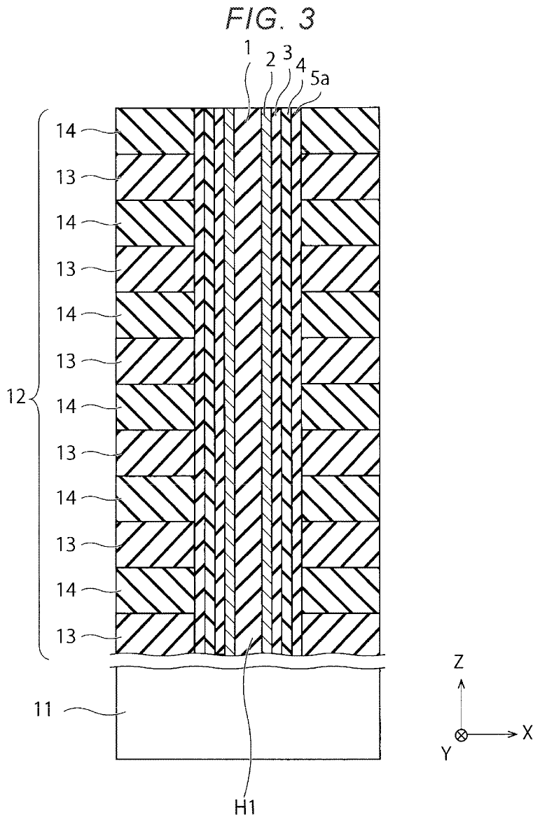

Next, the insulating film 5a, the charge storage layer 4, the tunnel insulating film 3, the channel semiconductor layer 2, and the core insulating film 1 are sequentially formed on side surfaces of the stacked films 12 in each of the memory holes H1 (FIG. 3). The insulating film 5a, the charge storage layer 4, the tunnel insulating film 3, and the channel semiconductor layer 2 have a tubular shape extending in the Z direction. The core insulating film 1 has a columnar shape extending in the Z direction.

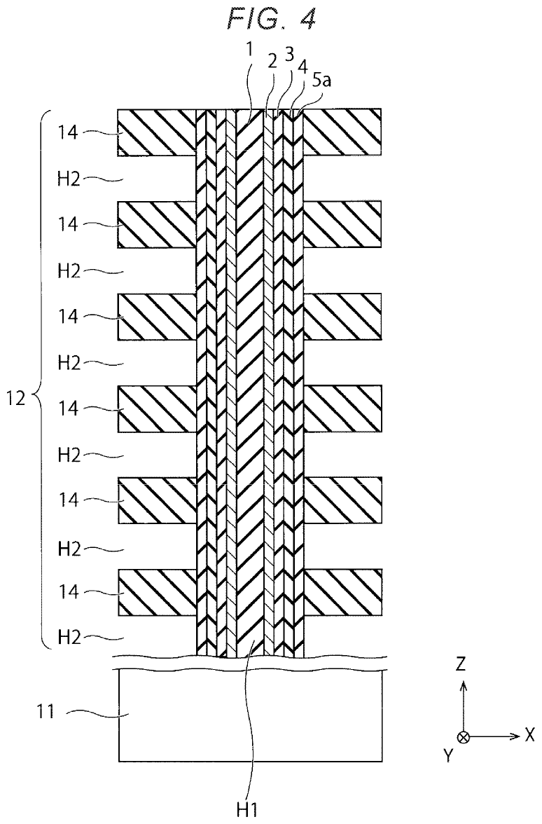

Next, a plurality of slits (not shown) are formed in the stacked film 12, and the sacrificial layer 13 is removed from the slits with a chemical solution such as a phosphoric acid aqueous solution. As a result, a plurality of recessed portions H2 are formed in the stacked film 12 (FIG. 4). The recessed portion H2 is an example of the first recessed portion.

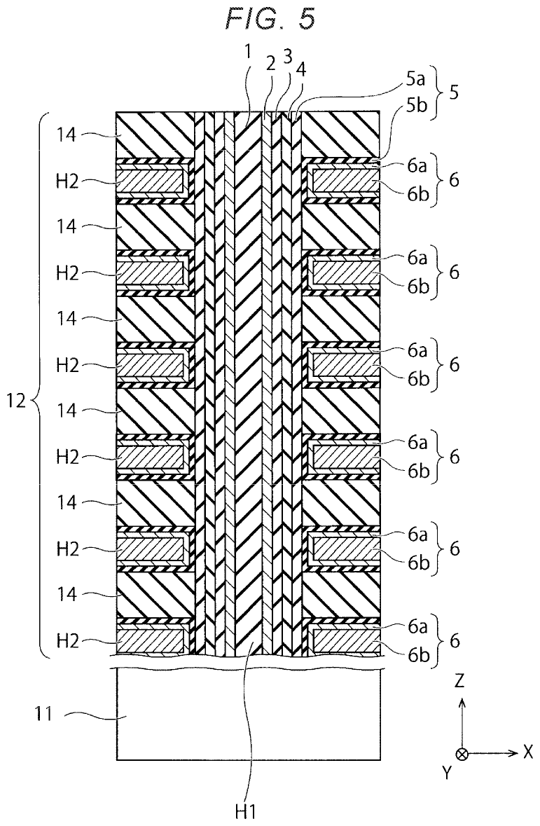

Next, the insulating film 5b, the barrier metal layer 6a, and the electrode material layer 6b are sequentially formed on the surfaces of the insulating films 5a and 14 in each of the recessed portions H2 (FIG. 5). As a result, a block insulating film 5 including the insulating films 5a and 5b is formed. Furthermore, the electrode layer 6 including the barrier metal layer 6a and the electrode material layer 6b is formed in each recessed portion H2. Furthermore, the stacked film 12 alternately including the plurality of electrode layers 6 and the plurality of insulating films 14 is formed on the substrate 11. In this manner, the replacement step of replacing the sacrificial layer 13 with the electrode layer 6 is performed.

Each recessed portion H2 is formed between the two insulating films 14 adjacent to each other in the Z direction. In each recessed portion H2, the insulating film 5b, the barrier metal layer 6a, and the electrode material layer 6b are sequentially formed on the lower surface of the upper insulating film 14, the upper surface of the lower insulating film 14, and the side surface of the insulating film 5a. As a result, each electrode layer 6 is formed between the insulating films 14 with the insulating film 5b interposed therebetween.

As such, the semiconductor device of the present embodiment is manufactured (FIG. 5). FIG. 1 shows a part of the semiconductor device shown in FIG. 5.

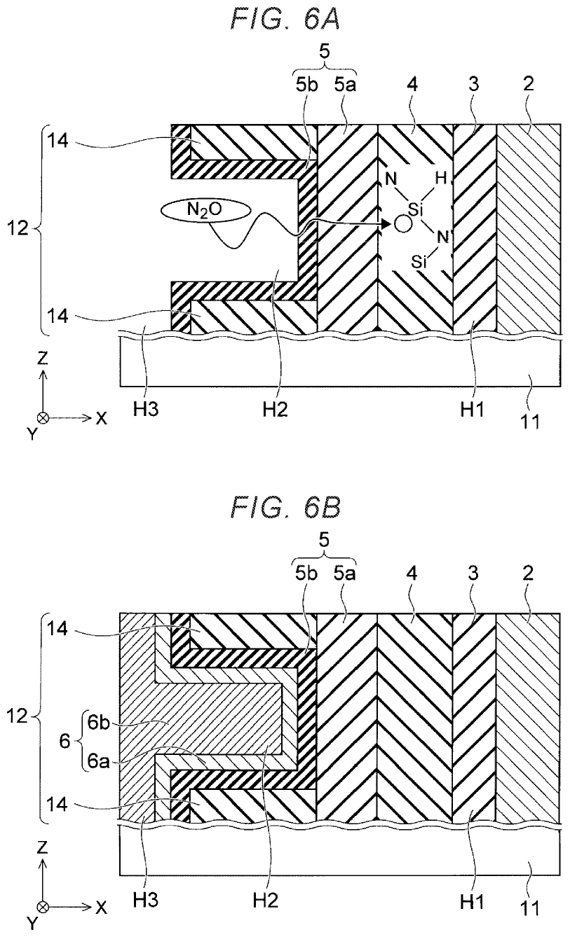

FIGS. 6A and 6B are cross-sectional views showing details of the method for manufacturing a semiconductor device according to the first embodiment.

FIG. 6A shows a rapid thermal process (RTP) performed in the step of FIG. 5. In the present embodiment, the RTP is performed after the formation of the insulating film 5b and before the formation of the barrier metal layer 6a. In the present embodiment, the insulating film 5b, the insulating film 5a, the charge storage layer 4, the tunnel insulating film 3, and the like are annealed by the RTP shown in FIG. 6A. For example, the temperature of the RTP is set to 1000° C. or higher, and the time of performing the RTP is set to equal to or shorter than 180 seconds.

FIG. 6A further shows a slit H3 formed in the stacked film 12. As described above, the slit H3 is used to remove the sacrificial layer 13 with a chemical solution such as a phosphoric acid aqueous solution from the slit H3. The slit H3 is further used to supply a gas for RTP (hereinafter, referred to as “annealing gas”) to the recessed portion H2. The annealing gas is, for example, N₂O gas (N represents nitrogen, and O represents oxygen). The annealing gas may be the other gases containing nitrogen and oxygen, for example, may be NO gas or NOₓ gas (x represents an integer of 2 or more). The annealing gas is an example of the first gas.

When the annealing gas is N₂O gas, NO gas, or NOₓ gas, the molecules contained in the annealing gas are N₂O molecules, NO molecules, or NOₓ molecules. The molecules contain N atoms and O atoms, but do not contain H (hydrogen) atoms. As described above, it is desirable that the molecules contained in the annealing gas of the present embodiment contain N atoms and O atoms, and do not contain H atoms. The molecules contained in the annealing gas are examples of the first molecule.

According to the present embodiment, by performing the RTP shown in FIG. 6A, it is possible to improve a film quality of the insulating films 5a and 5b and to reduce a hydrogen concentration in the charge storage layer 4. For example, by improving the film quality of the insulating films 5a and 5b, it is possible to reduce a leakage current at the time of writing data to the memory cell and to improve write saturation. In addition, by reducing the hydrogen concentration in the charge storage layer 4, it is possible to increase the dangling bond in the charge storage layer 4 as shown in FIG. 6A, and it is possible to improve the write efficiency. The hydrogen concentration (A₄) in the charge storage layer 4 after the RTP is, for example, equal to or lower than 1.0×10²⁰ atoms/cm³.

In addition, according to the present embodiment, it is possible to greatly reduce a hydrogen concentration in a film close to the recessed portion H2 and to slightly reduce a hydrogen concentration in a film far from the recessed portion H2. As a result, it is possible to realize the relationship of A₃≥A₄≥A₅ₐ≥A_{5b} with respect to the hydrogen concentrations A₃, A₄, A₅ₐ, and A_{5b} in the tunnel insulating film 3, the charge storage layer 4, the insulating film 5a, and the insulating film 5b. According to such a concentration gradient, it is possible to further improve the write efficiency.

FIG. 6B shows subsequent processing performed in the step of FIG. 5. In the present embodiment, after performing the RTP described above, the barrier metal layer 6a and the electrode material layer 6b are sequentially formed in each recessed portion H2. In FIG. 6B, the same insulating film 5b, barrier metal layer 6a, and electrode material layer 6b are present in the plurality of recessed portions H2 or in the slits H3 connected to the recessed portions H2. Thereafter, the insulating film 5b, the barrier metal layer 6a, and the electrode material layer 6b in the slit H3 are removed, and the insulating film 5b, the barrier metal layer 6a, and the electrode material layer 6b are divided for each recessed portion H2. FIG. 5 shows the insulating film 5b, the barrier metal layer 6a, and the electrode material layer 6b after being divided into each recessed portion H2.

Next, the material of the insulating film 5b will be described.

The insulating film 5b is, for example, a HfOₓ film. When the insulating film 5b is the HfOₓ film, it is possible to improve the charge retention characteristics and the erasing characteristics of the memory cell as compared with a case where the insulating film 5b is the AlOₓ film. On the other hand, when the insulating film 5b is the HfOₓ film, there is a concern that the write characteristics of the memory cell may deteriorate as compared with a case where the insulating film 5b is the AlOₓ film.

Therefore, in the present embodiment, the insulating film 5b, the insulating film 5a, the charge storage layer 4, the tunnel insulating film 3, and the like are annealed by the RTP described above. As a result, it is possible to solve the problem of deterioration of the write characteristics of the memory cell by improving the write saturation and the write efficiency of the memory cell.

According to the RTP of the present embodiment, it is possible to improve the charge retention characteristics and the erasing characteristics of the memory cell even when the insulating film 5b is the HfOₓ film or when the insulating film 5b is other than the HfOₓ film (for example, the AlOₓ film). According to the RTP of the present embodiment, when the insulating film 5b is the HfOₓ film, it is possible to improve the charge retention characteristics and the erasing characteristics of the memory cell, and it is possible to further improve the write characteristics of the memory cell.

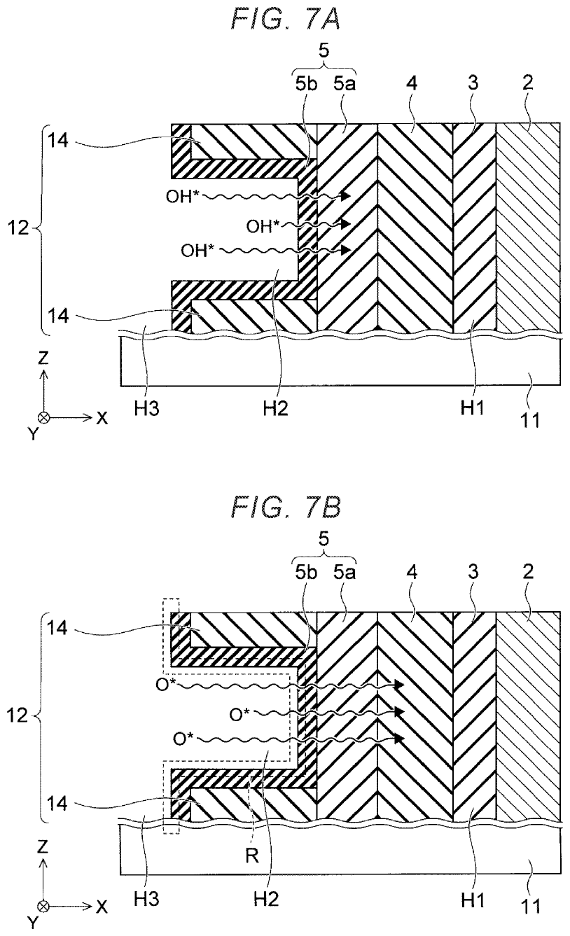

FIGS. 7A and 7B are cross-sectional views for comparing the method for manufacturing a semiconductor device according to a comparative example of the first embodiment and the method for manufacturing a semiconductor device according to the first embodiment.

FIG. 7A shows RTP performed when the semiconductor device of a comparative example of the first embodiment is manufactured. The RTP shown in FIG. 7A is performed using an OH radical (hydroxyl radical) generated from the annealing gas. The annealing gas includes, for example, an O₂ gas and an H₂ gas.

FIG. 7B shows RTP performed when the semiconductor device of the first embodiment is manufactured, as shown in FIG. 6A. The RTP shown in FIG. 7B is performed using an O radical (oxygen radical) generated from the annealing gas. The annealing gas includes, for example, N₂O gas, NO gas, or NOₓ gas, but does not include a gas containing an H atom.

Reference symbol R shown in FIG. 7B indicates a region near the surface of the insulating film 5b. The O radical is generated, for example, by a chemical reaction of N₂O gas, NO gas, or NOₓ gas near the surface of the insulating film 5b. The O radical enters the insulating film 5b, the insulating film 5a, the charge storage layer 4, the tunnel insulating film 3, and the like and reacts with the H atom. As a result, the H concentration decreases in the insulating film 5b, the insulating film 5a, the charge storage layer 4, and the tunnel insulating film 3. For example, the O radical diffuses to the charge storage layer 4 and dissociates a H terminal in the charge storage layer 4, thereby decreasing the H concentration in the charge storage layer 4.

In the step shown in FIG. 7B, after performing the RTP, the insulating film 5b, the insulating film 5a, the charge storage layer 4, the tunnel insulating film 3, and the like may be treated using a deuterium (D₂) gas. As a result, it is possible to terminate the dangling bond of the charge storage layer 4 or the like with deuterium.

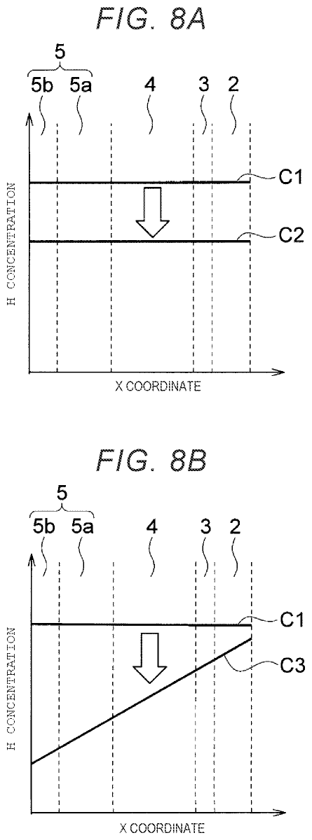

FIGS. 8A and 8B are graphs showing characteristics of the semiconductor device of the first embodiment.

Each of FIG. 8A and FIG. 8B shows the H concentration in the insulating film 5b, the insulating film 5a, the charge storage layer 4, the tunnel insulating film 3, and the channel semiconductor layer 2 on a straight line extending in the X direction. The straight line passes through a point on a central axis of the memory hole H1 shown in FIGS. 1 and 5. That is, the straight line extends parallel to a radial direction of the central axis of the memory hole H1. Each of FIG. 8A and FIG. 8B shows a local H concentration at an individual point on the straight line extending in the X direction. The X direction is an example of the first direction.

A line C1 shown in FIG. 8A and FIG. 8B indicates the H concentration before performing the RTP. A line C2 shown in FIG. 8A indicates the H concentration after performing the RTP. A line C3 shown in FIG. 8B also indicates the H concentration after performing the RTP. According to the RTP of the present embodiment, it is possible to achieve the H concentration indicated by the line C3 instead of the line C2.

In the example shown in FIG. 8B, the H concentration indicated by the line C1, that is, the H concentration before performing the RTP is substantially constant in the insulating film 5b, the insulating film 5a, the charge storage layer 4, the tunnel insulating film 3, and the channel semiconductor layer 2. The H concentration on the line C1 is, for example, equal to or higher than 1.0×10²¹ atoms/cm³.

On the other hand, the H concentration indicated by the line C3, that is, the H concentration after performing the RTP, increases as it progresses in the X direction. The reason is that the RTP of the present embodiment greatly reduces the H concentration at the position close to the recessed portion H2 and slightly reduces the hydrogen concentration at the position far from the recessed portion H2. The line C3 has a monotonically increasing function in which the H concentration increases as X increases. On the line C3, a relationship of A₃≥A₄≥A₅ₐ≥A_{5b} is established between the H concentration A₃ at a certain point in the tunnel insulating film 3, the H concentration A₄ at a certain point in the charge storage layer 4, the H concentration A₅ₐ at a certain point in the insulating film 5a, and the H concentration A_{5b} at a certain point in the insulating film 5b. According to such a concentration gradient, it is possible to improve the write efficiency of the memory cell. The line C3 is a straight line in which the relationship of A₃≥A₄≥A₅ₐ≥A_{5b} is established, but alternatively, the line C3 may be a curve in which the relationship of A₃≥A₄≥A₅ₐ≥A_{5b} is established.

On the line C3, the hydrogen concentration A₄ at all of the points in the charge storage layer 4 may be equal to or lower than 1.0×10²⁰ atoms/cm³, or only the hydrogen concentration A₄ at some of the points in the charge storage layer 4 may be equal to or lower than 1.0×10²⁰ atoms/cm³. For example, the average of the hydrogen concentration A₄ in the charge storage layer 4 may be equal to or lower than 1.0×10²⁰ atoms/cm³. In the present embodiment, it is desirable that the hydrogen concentration A₄ at all the points in the charge storage layer 4 is equal to or lower than 1.0×10²⁰ atoms/cm³.

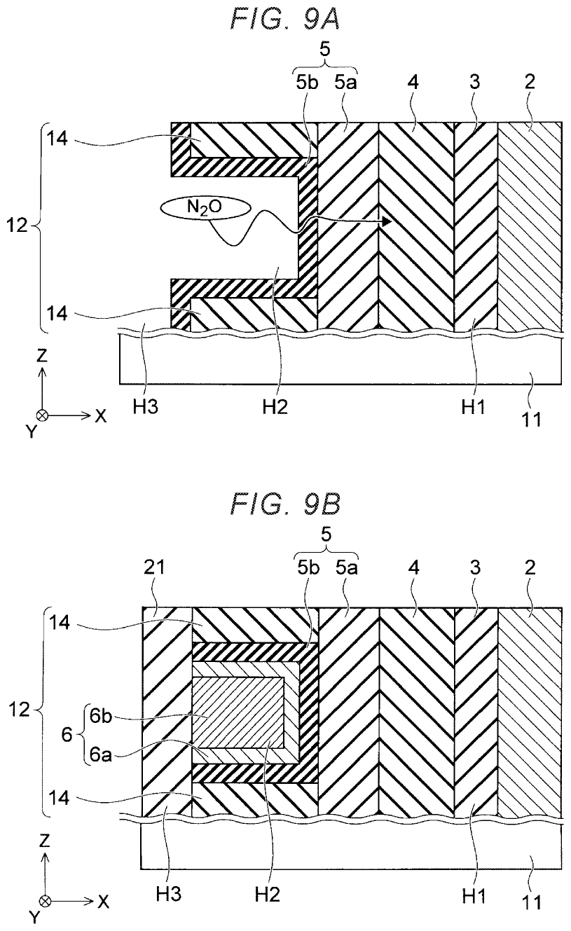

FIGS. 9A and 9B are cross-sectional views showing details of the method for manufacturing a semiconductor device according to the first embodiment.

FIGS. 9A and 9B show the steps shown in FIG. 5, as in FIG. 6A and FIG. 6B. First, the insulating film 5b is formed in the slit H3 and the recessed portion H2, and then RTP is performed (FIG. 9A). Next, the barrier metal layer 6a and the electrode material layer 6b are sequentially formed in the slit H3 and the recessed portion H2, the electrode material layer 6b, the barrier metal layer 6a, and the insulating film 5b are removed from the slit H3, and the insulating film 21 is formed in the slit H3 (FIG. 9B). As such, the semiconductor device of the present embodiment is manufactured.

The slit H3 may be filled only with the insulating film 21 or may be filled with the insulating film 21 and the wiring layer. Accordingly, it is possible to provide a wiring (for example, a gate line) in the slit H3.

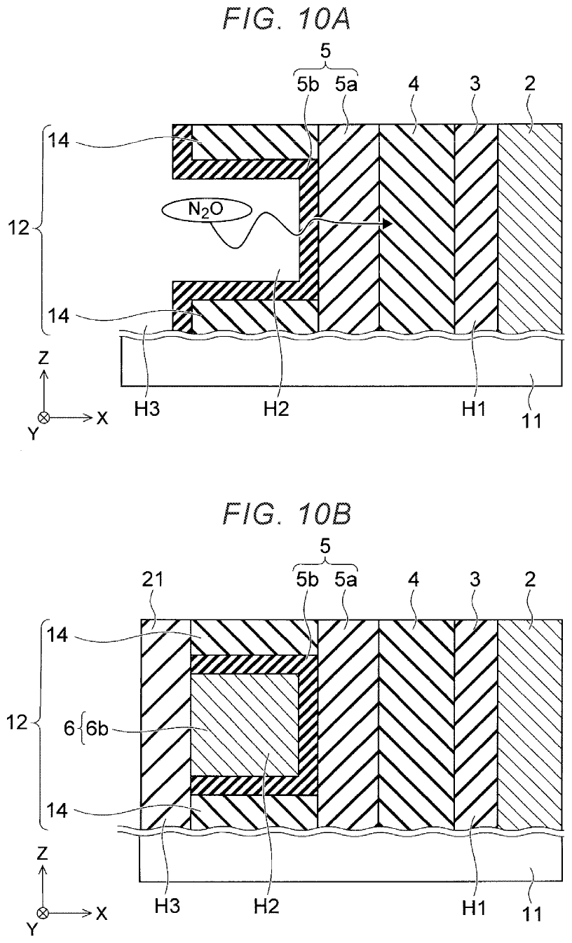

FIGS. 10A and 10B are cross-sectional views showing the method for manufacturing a semiconductor device according to a modification example of the first embodiment.

The steps in FIG. 10A and FIG. 10B are performed in the same manner as the steps in FIG. 9A and FIG. 9B. However, in the step of FIG. 10B, the barrier metal layer 6a is not formed. As described above, the step of forming the barrier metal layer 6a may be omitted.

The electrode material layer 6b in FIG. 9B or FIG. 10B may be a metal layer other than the W layer, for example, may be a molybdenum (Mo) layer. In addition, the barrier metal layer 6a in FIG. 9B may be a metal layer other than the TiN film, for example, may be a titanium-containing film other than the TiN film or a film containing a metal element other than titanium (for example, tantalum).

As described above, in the present embodiment, the relationship of A₃≥A₄≥A₅ₐ≥A_{5b} is established between the H concentration A₃ in the tunnel insulating film 3, the H concentration A₄ in the charge storage layer 4, the H concentration A₅ₐ in the insulating film 5a, and the H concentration A_{5b} in the insulating film 5b. Therefore, according to the present embodiment, it is possible to form a memory cell having suitable characteristics. For example, by realizing the relationship of A₃≥A₄≥A₅ₐ≥A_{5b}, it is possible to improve the write saturation and the write efficiency of the memory cell. In addition, according to the present embodiment, by performing the RTP using a gas containing nitrogen and oxygen (for example, N₂O gas), it is possible to realize the relationship of A₃≥A₄≥A₅ₐ≥A_{5b}.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a stacked film including a plurality of electrode layers and a plurality of first insulating films alternately stacked on top of one another;
a second insulating film extending along an upper surface, a lower surface, and a side surface of at least one electrode layer of the plurality of electrode layers;
a charge storage layer extending along a side surface of the second insulating film, with a third insulating film interposed between the second insulating film and the charge storage layer; and
a semiconductor layer extending along a side surface of the charge storage layer, with a fourth insulating film interposed between the charge storage layer and the semiconductor layer,
wherein a hydrogen concentration in the fourth insulating film is equal to or higher than a hydrogen concentration in the charge storage layer,
the hydrogen concentration in the charge storage layer is equal to or higher than a hydrogen concentration in the third insulating film, and
the hydrogen concentration in the third insulating film is equal to or higher than a hydrogen concentration in the second insulating film.

2. The semiconductor device according to claim 1,
wherein the second insulating film includes hafnium, aluminum, or zirconium.

3. The semiconductor device according to claim 2,
wherein the second insulating film further includes oxygen.

4. The semiconductor device according to claim 1,
wherein the hydrogen concentration in the charge storage layer is equal to or lower than about 1.0×10²⁰ atoms/cm³.

5. The semiconductor device according to claim 1,
wherein the fourth insulating film, the charge storage layer, the third insulating film, and the second insulating film each include hydrogen atoms as impurity atoms.

6. The semiconductor device according to claim 1,
wherein the hydrogen concentrations in the fourth insulating film, the charge storage layer, the third insulating film, and the second insulating film each increase in a first direction from the second insulating film toward the fourth insulating film.

7. A method for manufacturing a semiconductor device, comprising:
forming a stacked film including a plurality of first layers and a plurality of first insulating films alternately stacked on top of one another;
forming a charge storage layer extending along a side surface of the first layer, with a third insulating film interposed between the charge storage layer and the third insulating film;
forming a semiconductor layer extending along a side surface of the charge storage layer, with a fourth insulating film interposed between the charge storage layer and the semiconductor layer;
removing the first layer to form a plurality of first recessed portions in the stacked film;
forming a second insulating film in each of the first recessed portions;
annealing the second insulating film using a first gas containing nitrogen and oxygen; and
after the annealing the second insulating film, forming a plurality of electrode layers positioned in the first recessed portions, respectively.

8. The method for manufacturing a semiconductor device according to claim 7,
wherein the first gas includes a first molecule containing nitrogen and oxygen.

9. The method for manufacturing a semiconductor device according to claim 8,
wherein the first molecule does not contain hydrogen.

10. The method for manufacturing a semiconductor device according to claim 7,
wherein the first gas contains N₂O gas, NO gas, or NOₓ gas, in which N represents nitrogen, O represents oxygen, and x represents an integer equal to or larger than 2.

11. The method for manufacturing a semiconductor device according to claim 7,
wherein the annealing the second insulating film includes a rapid thermal process (RTP).

12. The method for manufacturing a semiconductor device according to claim 7,
wherein the annealing the second insulating film is performed at about 1000° C. or higher.

13. The method for manufacturing a semiconductor device according to claim 7,
wherein the annealing the second insulating film is performed using an oxygen radical generated from the first gas.

14. The method for manufacturing a semiconductor device according to claim 7,
wherein after the annealing the second insulating film and before forming the electrode layers, treating the charge storage layer using a deuterium gas.

15. The method for manufacturing a semiconductor device according to claim 7,
wherein the second insulating film includes hafnium, aluminum, or zirconium.

16. The method for manufacturing a semiconductor device according to claim 15,
wherein the second insulating film further includes oxygen.

17. The method for manufacturing a semiconductor device according to claim 7,
wherein
a hydrogen concentration in the fourth insulating film is equal to or higher than a hydrogen concentration in the charge storage layer,
the hydrogen concentration in the charge storage layer is equal to or higher than a hydrogen concentration in the third insulating film, and
the hydrogen concentration in the third insulating film is equal to or higher than a hydrogen concentration in the second insulating film.

18. The method for manufacturing a semiconductor device according to claim 7,
wherein the charge storage layer has a hydrogen concentration equal to or lower than about 1.0×10²⁰ atoms/cm³.

19. The method for manufacturing a semiconductor device according to claim 7,
wherein the fourth insulating film, the charge storage layer, the third insulating film, and the second insulating film each include hydrogen atoms as impurity atoms.

20. The method for manufacturing a semiconductor device according to claim 7,
wherein hydrogen concentrations in each of the fourth insulating film, the charge storage layer, the third insulating film, and the second insulating film increases in a first direction from the second insulating film toward the fourth insulating film.
